(19) United States
(12) Patent Application Publication
(10) Pub. No.: US 2011/0121459 A1
(43) Pub. Date: May 26, 2011

(54) SEMICONDUCTOR INTERCONNECTION

(75) Inventors: Takashi Onishi, Kobe-shi (JP); Masao Mizuno, Kobe-shi (JP); Hirotaka Ito, Kobe-shi (JP); Kazuyuki Kohama, Sakyo-ku (JP); Kazuhiro Ito, Sakyo-ku (JP); Susumu Tsukimoto, Sakyo-ku (JP); Masanori Murakami, Sakyo-ku (JP)

(73) Assignee: Kabushiki Kaisha Kobe Seiko Sho (Kobe Steel, Ltd.), Kobe-shi (JP)

(21) Appl. No.: 13/003,181

(22) PCT Filed: Jul. 10, 2009
(86) PCT No.: PCT/JP09/62618

§ 371 Date: Jan. 7, 2011

(30) Foreign Application Priority Data
Jul. 14, 2008 (JP) 2008-183014

(51) Int. Cl. H01L 23/535

(52) U.S. Cl. 257/751; 257/E23.145

(57) ABSTRACT

Provided is a semiconductor interconnection wherein a barrier layer different from a TiO₂ layer is formed on an interface between an insulating film and a Cu interconnection without increasing electrical resistivity of the Cu interconnection. In the semiconductor interconnection, a Cu interconnection containing Ti is embedded in a trench arranged on an insulating film on the semiconductor substrate, and a TiC layer is formed between the insulating film and the Cu interconnection. The insulating film is preferably composed of SiCO or SiCN. The thickness of the TiC layer is preferably 3-30 nm.

### TECHNICAL FIELD

The present invention relates to semiconductor devices. More specifically, it relates to interconnections in semiconductor devices such as silicon (Si) semiconductor devices represented typically by ultra-large-scale integrated circuits (ULSIs).

### BACKGROUND ART

The design rule of semiconductor devices such as large-scale integration circuits (LSIs) has become more and more reduced so as to satisfy requirements for larger packing densities and higher-speed signal transmission of the LSIs. The interconnection pitch, width and interval between interconnections, and an interlayer contact hole (via) for connecting the interconnections with each other have been reduced in size. Further, the formation of an interconnection in a multilayer structure have been under study in order to cope with higher integration of semiconductor devices.

Furthermore, the resistance of the interconnection is increased together with miniaturization and increase in packing density of interconnection circuits, which causes delay of the signal transmission. Thus, the formation of a Cu-based interconnection has been proposed in which an interconnection material based on Cu (hereinafter referred to as a Cu-based interconnection material) is used as an interconnection material that can have a lower electric resistance.

A damascene interconnection technique has been known as a method for forming a Cu-based interconnection having a multi layer structure (as disclosed typically in Japanese Unexamined Patent Application Publication (JP-A) No. 2001-7050). In the damascene technique, for example, interconnection grooves (interconnection trenches) or interlayer contact holes (hereinafter collectively referred to as trenches) are formed in an interlayer insulating film provided on a semiconductor substrate. Then, the Cu-based interconnection material, such as pure Cu or a Cu alloy, is applied to the surface of the trench, which is heated to fluidize the Cu-based interconnection material. The Cu-based material is thus embedded into the trenches to thereby form a Cu interconnection.

In use of the Cu-based interconnection material, when the interlayer insulating film is directly brought into contact with the Cu interconnection, Cu may diffuse into the insulating film, which degrades insulation property of the insulating film. In order to prevent diffusion of the Cu into the interlayer insulating film, it is necessary to provide a barrier layer between the insulating film and the Cu interconnection. The barrier layer is required to exhibit barrier properties even when heated to high temperatures of about 500° C. to 700° C. so as to embed the Cu interconnection into the trenches. For this reason, the barrier layer is formed by using a metal nitride film, such as a TaN film or a TiN film. Such a barrier layer, however, has a high electrical resistivity as compared to that of a metal film, which disadvantageously increases the electrical resistivity of the interconnection.

To reduce the electrical resistivity of the Cu interconnection, a thin, uniform barrier layer should be formed. As a technique for forming a thin, uniform barrier layer, there has been proposed a technique of forming a TaN layer though atomic layer deposition (ALD) (Non Patent Literature (NPL) 1). This technique, however, has not yet been mature so as to be practically usable. Additionally, in recent years, the width of the interconnection groove or the diameter of the contact hole has become smaller and smaller, and the depth-to-width ratio of the interconnection groove or the depth-to-diameter ratio of the contact hole has become larger and larger. This makes it more difficult to form the barrier layer.

Thus, the present applicants have paid attention to vapor quenching in a sputtering process so as to uniformly form an extremely thin barrier film between the Cu interconnection and the interlayer insulating film, and have proposed techniques in which an extremely thin barrier film is formed using a non-equilibrium solid solution phenomenon (Patent Literature (PTL) 1 and 2, and NPL 2). In these techniques, the Cu alloy containing Ti, which element has a small solubility limit with respect to Cu, is formed in the interconnection groove or on the surface of the contact hole, and then heated and pressed to be separated into two phases, namely, Cu and Ti. Then, Ti abnormally diffuses into between the Cu interconnection and the interlayer insulating film or on the surface of the Cu-based interconnections, to form a Ti-enriched layer. Of the resulting Ti-enriched layers, a Ti-enriched layer formed between the Cu interconnection and the interlayer insulating film serves as a barrier layer for preventing the diffusion of Cu into the insulating film.

Above-mentioned PTL 1 and PTL 2 disclose the use of silicon oxide or silicon nitride as the insulating film. These literatures disclose, in their working examples, that a Cu alloy thin film is formed on an SiOF film used as the insulating film, the Cu alloy thin film is heated and thereby yields a TiO₂ layer at the interlayer between the Cu alloy and the insulating film. In addition, these literatures demonstrate that the TiO₂ layer serves as a barrier layer.

### CITATION LIST

### Patent Literature

PTL 1: JP-A No. 2007-258256
PTL 2: JP-A No. 2008-21807

### Non Patent Literature

NPL 1: “Ultra Thin TaN Barrier Layer Deposition for Cu Metallization using ALD”, Proceedings of The 65th Symposium on Semiconductors and Integrated Circuits Technology, Electronic Material Committee of The Electrochemical Society of Japan, p. 62-65 (2003)
NPL 2: “Self-Formation of Barrier Material by Cu Alloy Interconnections” Proceedings of 10th Workshop on Stress Induced Phenomena in LSI Metallization, Thin Film and Surface Physics Subcommittee, The Japan Society of Applied Physics, p. 28-29 (2004)

### SUMMARY OF INVENTION

### Technical Problem

An object of the present invention is to provide a semiconductor interconnection including a barrier layer other than TiO₂ layer present at an interface between an insulating film and a Cu interconnection without increasing the electrical resistivity of the Cu interconnection.

### Solution to Problem

The present inventors made intensive investigations in order to form a barrier layer at an interface between an insulating film and a Cu interconnection without increasing the electrical resistivity of the Cu interconnection. As a result, they have found that a TiC layer serves as a barrier layer and is useful for reducing the electrical resistivity of the Cu interconnection. The present invention has been made based on these findings.

Specifically, the present invention achieves the above object and provides a semiconductor interconnection which includes an insulating film arranged on or above a semiconductor substrate; and a copper (Cu) interconnection containing titanium (Ti) and embedded in respective trenches provided in the insulating film, in which the semiconductor interconnection further includes a titanium carbide (TiC) layer present between the insulating film and the Cu interconnection. The insulating film may be composed typically of SiCO or SiCN. The TiC layer preferably has a thickness of 3 to 30 nm.

### Advantageous Effects of Invention

The present invention allows a Cu interconnection to have a lower electrical resistivity and enables higher-speed signal transmission of a semiconductor interconnection by forming a TiC layer as a barrier layer between an insulating film and the Cu interconnection.

### BRIEF DESCRIPTION OF DRAWINGS

FIG. 1 shows a semiconductor interconnection according to one embodiment of the present invention.

FIG. 2 shows how the electrical resistivity of a Cu alloy thin film varies depending on the heat treatment time.

### DESCRIPTION OF EMBODIMENTS

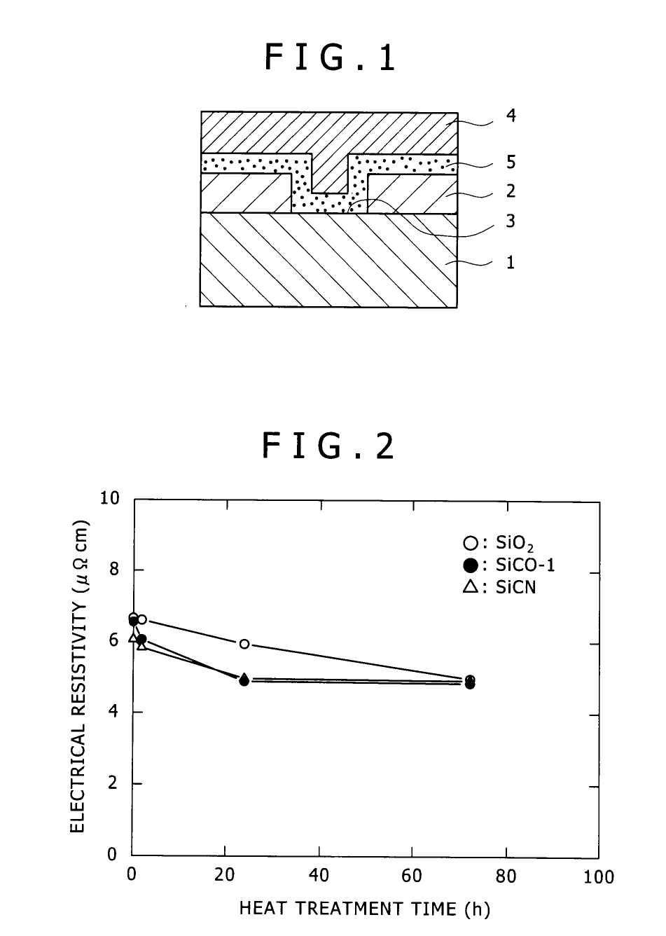

As illustrated in FIG. 1, the semiconductor interconnection according to the present invention includes an insulating film 2 arranged on a semiconductor substrate 1; and a Ti-containing Cu interconnection 4 embedded in a trench 3 provided in the insulating film 2, in which a TiC layer 5 is continuously present between the insulating film 2 and the Cu interconnection 4. The TiC layer 5 serves as a barrier layer which prevents the diffusion and migration of Cu contained in the Cu interconnection into the insulating film.

The TiC layer is formed between the insulating film and the Cu interconnection through heat treatment for embedding a Ti-containing Cu alloy thin film in a trench provided in the insulating film to form a Cu interconnection, as is mentioned below. Specifically, the heat treatment allows Ti contained in the Cu interconnection to diffuse into an interface between the Cu interconnection and the insulating film and to be combined with carbon (C) contained in the insulating film to thereby form the TiC layer. The present invention allows the Cu interconnection to have a lower electrical resistivity by forming the TiC layer as a barrier layer; and this eliminates the need of separately forming a metal nitride film such as TaN or TiN film as a barrier layer on an insulating film as in customary techniques.

To ensure satisfactory barrier properties, the TiC layer preferably has a thickness of 3 nm or more, more preferably 5 nm or more, and furthermore preferably 8 nm or more. However, the TiC layer, if having an excessively large thickness, may cause the Cu interconnection to have a higher electrical resistivity due to a reduced effective cross-sectional area (an area determined by subtracting the area of the barrier layer from the area of the interconnection trench) of the Cu interconnection. Accordingly, the TiC layer preferably has a thickness of about 30 nm or less, more preferably 28 nm or less, and furthermore preferably 25 nm or less.

The thickness of the TiC layer may be measured by observing a cross section where the multilayer structure of films can be observed, with a transmission electron microscope (TEM).

Next, a method for fabricating a semiconductor interconnection according to the present invention will be illustrated. The semiconductor interconnection according to the present invention may be fabricated in the following manner. Initially, an insulating film containing carbon (C) is provided on a semiconductor substrate, and one or more trenches (interconnection trenches or grooves and/or interlayer contact holes) are formed in the insulating film. Next, a Ti-containing Cu alloy thin film is deposited on the trenches typically through sputtering and is heated. Specifically, using an insulating film containing C and Si, trenches are provided in the insulating film, and the Cu alloy thin film is deposited in the trenches and is heated. This allows Ti contained in the Cu alloy thin film to diffuse into the interface between the insulating film and the Cu alloy (thin film) and is combined with C in the insulating film and thereby yields the TiC layer.

The insulating film containing C may be a silicon oxide film (SiO₂) further containing C formed through chemical vapor deposition (CVD), and specific examples thereof include films composed of SiCO or SiCN. The SiCO film and SiCN film are amorphous films. The SiCO is considered as a mixture of SiO₂ and SiC; and the SiCN is considered as a mixture of SiO₂ and SiN.

The insulating film preferably has a C content of, for example, 17 atomic percent or more. This is because the insulating film, if having a C content of less than 17 atomic percent, may cause a TiSi layer present between the insulating film and the Cu interconnection and may not sufficiently help the Cu interconnection to have a lower electrical resistivity. The C content is preferably 18 atomic percent or more, and more preferably 20 atomic percent or more. The upper limit of the C content is about 40 atomic percent. The upper limit of the C content is preferably 35 atomic percent or less, and more preferably 30 atomic percent or less. The insulating film containing C may be formed on a surface of the semiconductor substrate according to a common procedure.

After the insulating film is provided on the surface of the semiconductor substrate, one or more trenches are formed in the insulating film, and a Ti-containing Cu alloy thin film is provided in the respective trenches. The trenches include interconnection trenches in which a Cu interconnection will be embedded; and interlayer contact holes for connecting Cu interconnections with each other.

The Cu alloy thin film preferably has a Ti content of 0.5 to 15 atomic percent. The Cu alloy thin film, if having a Ti content of less than 0.5 atomic percent, may cause insufficient enrichment of Ti in the interface between the insulating film and the Cu interconnection, and this may cause the TiC layer formed in the interface to have an excessively small thickness and to exhibit insufficient barrier properties. In addition, such insufficient content of the enriched Ti may cause the TiC layer formed along the interface to be discontinuous and to thereby have inferior barrier properties. Accordingly, the Ti content may be 0.5 atomic percent or more, preferably 1 atomic percent or more, and more preferably 3 atomic percent or more. However, if the Ti content is excessively high, excessive Ti not constituting the TiC layer is dissolved in the Cu interconnection through solid solution, or precipitates in the Cu interconnection to form precipitates. This is because there is limitation on the thickness of the TiC layer formed in the interface between the insulating film and the Cu interconnection. The dissolved Ti and Ti precipitates cause the Cu interconnection to have a higher electrical resistivity. Accordingly, the Ti content may be 15 atomic percent or less, preferably 13 atomic percent or less, and more preferably 10 atomic percent or less.

The residual composition of the Cu alloy thin film is Cu, but may further contain one or more other components such as Ag, Mg, Na, Fe, Si, Dy, N, and H.

The way to deposit the Ti-containing Cu alloy thin film in the trenches is not especially limited, and examples thereof usable herein include sputtering and (arc) ion plating. The sputtering can be performed typically through long throw sputtering.

The way to deposit the Cu alloy thin film by sputtering will be explained below.

The Ti-containing Cu alloy thin film may be deposited, for example, by carrying out sputtering in an atmosphere of an inert gas using, as a sputtering target, a Ti-containing Cu alloy target or a target of pure Cu on which one or more Ti chips are mounted.

Exemplary inert gases usable herein include helium, neon, argon, krypton, xenon, and radon gases. Preferably, argon or xenon is used. Among them, argon is relatively inexpensive and is advantageously usable. The inert gas may contain N₂ gas and/or H₂ gas.

Other sputtering conditions (such as ultimate pressure, sputtering gas pressure, discharge power density, substrate temperature, and distance between electrodes) may be adjusted as appropriate within the usual ranges. The thickness of the Cu alloy thin film deposited over the respective trenches may be changed depending on the depths of the trenches, and it is enough to deposit the Cu alloy thin film so as to have a thickness at least equal to the depths of the trenches.

It is also accepted that a Ti-containing Cu alloy thin film is initially deposited as a seed layer so as to conform the dimensions of the trenches, and a pure Cu thin film is then deposited as a Cu interconnection on the trenches covered by the Cu alloy thin film.

Exemplary techniques for forming the pure Cu thin film usable herein include, but are not especially limited to, electrolytic plating, chemical vapor deposition (CVD), sputtering, and (arc) ion plating. Among them, electrolytic plating is preferably employed, because this technique fills the trenches with the pure Cu thin film while gradually embedding the thin film from the bottom of the trenches and allows the pure Cu to be embedded into every corner of the trenches, even when the trenches have a small minimum width and are deep.

After forming the Cu alloy thin film in the trenches, or after the Cu alloy thin film as a seed layer is formed along the dimensions of the trenches in the above manner, the pure Cu thin film is formed as the Cu interconnection. A heat treatment through heating to 400° C. or higher is preferably performed in order to allow Ti in the Cu alloy thin film to diffuse. The heating, if performed at a temperature lower than 400° C., may not allow Ti in the Cu alloy thin film to diffuse sufficiently into the interface between the Cu alloy and the insulating film, and this may impede the formation of the TiC layer in the interface, resulting in inferior barrier properties. Additionally, such low-temperature heat treatment may cause undiffused Ti to remain in a larger amount in the Cu interconnection to thereby cause the Cu interconnection to have a higher electrical resistivity. The higher the heating temperature is, the better. The heating temperature is preferably 450° C. or higher, and more preferably 500° C. or higher. The upper limit of the heating temperature is about 700° C. Providing an apparatus for performing heating at a temperature higher than 700° C. is practically difficult, and the heating, if performed at an excessively high temperature, causes the deformation of the semiconductor substrate. The upper limit of the heating temperature is therefore preferably 650° C., and more preferably 600° C.

The atmosphere in heating is preferably a nonoxidizing atmosphere or vacuum atmosphere. The heating, if performed in an oxidizing atmosphere, may cause Ti dissolved in the Ti-containing Cu alloy thin film to diffuse and be enriched preferentially in a surface in contact with the oxidizing gas to form a TiOX. This consumes the dissolved Ti in the Cu alloy thin film, thereby impedes the stable formation of the TiC layer in the interface between the Cu alloy and the insulating film, and the TiC layer fails to exhibit barrier effects. The heating atmosphere is preferably an atmosphere whose oxygen content has been minimized.

The nonoxidizing atmosphere may typically be the inert gas atmosphere. The vacuum atmosphere may typically be at a pressure of 133×10⁻¹⁰ Pa or less (1×10⁻¹⁰ Torr or less).

The heating time may be set according to the heating temperature so as to form the TiC layer in the interface between the Cu alloy and the insulating film. Specifically, the heating time is preferably set short when the heating temperature is high; and the heating time is preferably set long when the heating temperature is low.

According to the present invention as described above, a TiC layer can be formed in the interface between a Cu interconnection and an insulating film by depositing a Ti-containing Cu alloy thin film in respective trenches provided in the insulating film and heating the Ti-containing Cu alloy thin film.

### EXAMPLES

The present invention will be illustrated in further detail with reference to several working examples below. It should be noted, however, that these examples are never intended to limit the scope of the present invention, and various alternations and modifications may be made without departing from the scope and spirit of the present invention and are all included within the technical scope of the present invention.

### Experimental Example 1

A series of substrates was prepared respectively by forming an insulating film on a surface of a silicon wafer, which insulating film had a component composition shown in Table 1 and had a thickness of 100 nm. A Cu alloy thin film containing Ti in a content of 10 atomic percent and having a thickness of 450 nm was deposited through DC magnetron sputtering on a surface of the insulating film. The films as indicated by SiCO-1 and SiCO-2, respectively, in Table 1 are both composed of SiCO, but have somewhat different component compositions from each other and are thereby differentiated by indicating as “SiCO-1” and “SiCO-2”.

The component composition of the insulating film was analyzed with a transmission electron microscope (TEM) equipped with an energy dispersive X-ray fluorescence spectrometer (EDX). The Cu alloy thin film was deposited through sputtering with a chip-on target using the Model HSM-552 sputtering system supplied by Shimadzu Corporation. The chip-on target used herein was one including a base pure Cu target (80 mm in diameter) on which three to six rectangular plate-like Ti chips 1 mm thick are mounted radially.

The sputtering conditions were as follows:

Base pressure: 133×10⁻³ Pa or less (1×10⁻³ Torr or less),

Sputtering atmosphere gas: Ar gas,

Sputtering gas pressure: 1.07×10⁻³ kPa (8×10⁻³ Torr),

Discharge power: 300 W,

Substrate temperature: room temperature (20° C., water cooling), and

Distance between electrodes: 100 mm.

After the film deposition, the samples were subjected to a heat treatment in a horizontal tubular furnace using a quartz tube. The heat treatment was performed by heating at 500° C. or 600° C. in an Ar gas atmosphere for 2 hours. The Ar gas atmosphere was obtained by blowing Ar gas into the horizontal tubular furnace at a flow rate of 20 mL/min. and thereby convecting the Ar gas in the furnace. The heat treatment temperatures are shown in Table 2.

The cross sections, where a laminate state of the films can be observed, of the samples after the heat treatment were observed with a transmission electron microscope (TEM) at a five hundred thousand magnification. The observation revealed that a barrier layer as shown in Table 2 was continuously formed between the insulating film and the Cu alloy thin film. The type and the thickness of the barrier layer as determined are shown in Table 2. The type of the barrier layer was analyzed through a selected area diffraction (SAD) image of the TEM.

Whether Cu diffused into the insulating film or not (barrier properties) was determined by observing an interface between the insulating film and the Cu alloy thin film over 2000 nm long. The barrier properties were evaluated by analyzing a Cu concentration profile in a depth direction from the Cu alloy thin film via the barrier layer and the insulating film to the silicon wafer by secondary ion mass spectrometry (SIMS).

The SIMS analysis was performed using a secondary ion mass spectrometer (Model 4500 supplied by ATOMIKA Instruments GmbH). The mass spectrometry of negative secondary ions was performed while applying Cs⁺ as a primary ion under conditions of 3 kV and 30 nA in an application area 300 μm wide and 420 μm long for an analyzing area 90 μm wide and 130 μm long. Cu atoms were detected as ⁶³Cu⁻ and ⁶⁵Cu⁻, and the barrier properties against the diffusion of Cu (Cu-barrier properties) were determined based on whether or not Cu was detected in the insulating film. A sample showing no diffusion of Cu into the insulating film was evaluated as having barrier properties (◯ (acceptable)), and one showing diffusion of Cu into the insulating film was evaluated as having no barrier properties (X (unacceptable)). The evaluation results are shown in Table 2.

Likewise, whether Si diffused or not was determined by performing an SIMS analysis as above and detecting whether Si atom was present in the Cu alloy thin film. A sample showing no diffusion of Si into the Cu alloy thin film was evaluated as being accepted (absence), and one showing diffusion of Si into the Cu alloy thin film was evaluated as being unaccepted (presence). The evaluation results are shown in Table 2.

Next, the electrical resistivity (pΩcm) of the Cu alloy thin film was determined by measuring the surface resistivity of the Cu alloy thin film of each sample after the heat treatment according to a four-pin probes sensing method; and multiplying the surface resistivity by the film thickness. The results are shown in Table 2.

Table 2 demonstrates that a compound between a component constituting the insulating film and Ti contained in the Cu alloy is formed between the insulating film and the Cu alloy thin film.

Samples No. 1 and No. 4 are samples using SiO₂ to constitute the insulating film and were found to include a TiSi layer formed between the insulating film and the Cu alloy thin film. The TiSi layer served as a barrier layer which prevents the diffusion of Cu in the Cu alloy thin film into the insulating film. However, Samples No. 1 and No. 4 showed diffusion of Si into the Cu alloy thin film and had a higher electrical resistivity of the Cu alloy thin film, because Si acted as a resistance. These samples showed diffusion of Si into the Cu alloy thin film, probably because TiSi is formed at a reaction rate lower than that of after-mentioned TiC, and this causes Si contained in the insulating film to diffuse into the Cu alloy thin film prior to the formation of TiSi.

In contrast, Samples Nos. 2, 3, 5, and 6 are samples using SiCO-1 or SiCN to constitute the insulating film and were found to include a TiC layer formed between the insulating film and the Cu alloy thin film. The TiC layer served as a barrier layer for preventing the diffusion of Cu in the Cu alloy thin film into the insulating film. In addition, these samples did not show diffusion of Si into the Cu alloy thin film and thereby each had a lower electrical resistivity of the Cu alloy thin film.

The insulating film SiCO-2 in Table 1 had a C content of less than 17 atomic percent and was found to include a TiSi layer formed at an interface between the insulating film and the Cu alloy thin film.

TABLE 1

Component composition (atomic percent)

| Insulating film | C | N | Si | O |
|---|---|---|---|---|
| SiO₂ | 0 | 0 | 33 | 67 |
| SiCO-1 | 21 | 0 | 25 | 17 |
| SiCO-2 | 15 | 0 | 20 | 30 |
| SiCN | 21 | 13 | 25 | 0.5 |

TABLE 2

| | | | | | | Presence | |
|---|---|---|---|---|---|---|---|
| | | Heat | Barrier layer | | | or absence | Electrical |
| | Insulating | treatment | | Thickness | Cu-barrier | of Si | resistivity |
| No. | film | temperature | Type | (nm) | properties | diffusion | (μΩcm) |
| 1 | SiO₂ | 500° C. | TiSi | 61 | ◯ | presence | 4.82 |
| 2 | SiCO-1 | | TiC | 19 | ◯ | absence | 3.56 |
| 3 | SiCN | | | 9 | ◯ | absence | 4.49 |
| 4 | SiO₂ | 600° C. | TiSi | 78 | ◯ | presence | 11.81 |
| 5 | SiCO-1 | | TiC | 28 | ◯ | absence | 2.93 |
| 6 | SiCN | | | 12 | ◯ | absence | 4.28 |

### Experimental Example 2

This experiment was performed under the same conditions as in Experimental Example 1, except for performing a heat treatment of samples after film deposition at a temperature of 600° C. for a duration of 5 minutes to 2 hours.

Table 3 shows the type of the insulating film, the heat treatment time, the type and thickness of a barrier film formed between the insulating film and the Cu alloy thin film, the presence or absence of diffusion of Cu into the insulating film (Cu-barrier properties), and the presence or absence of diffusion of Si into the Cu alloy thin film.

Table 3 demonstrates that a compound between a component constituting the insulating film and Ti contained in the Cu alloy was formed between the insulating film and the Cu alloy thin film, under any heat treatment conditions.

Samples Nos. 11 to 15 are samples using SiO₂ to constitute the insulating film and were found to include a TiSi layer as a barrier layer formed between the insulating film and the Cu alloy thin film. However, these samples showed diffusion of Si into the Cu alloy thin film and each had a higher electrical resistivity of the Cu alloy thin film, because Si acted as a resistance.

In contrast, Samples Nos. 16 to 27 are samples using SiCO-1 or SiCN to constitute the insulating film and were found to include a TiC layer formed between the insulating film and the Cu alloy thin film. Samples Nos. 16 to 27 showed no diffusion of Si into the Cu alloy thin film. However, Samples Nos. 16, 17, and 22 to 25 showed diffusion of Cu into the insulating film, because the TiC layer in these samples had a thickness of less than 3 nm and failed to serve as a barrier layer.

TABLE 3

| | | | | | | Presence |
|---|---|---|---|---|---|---|
| | | Heat | Barrier layer | | | or absence |
| | Insulating | treatment | | Thickness | Cu-barrier | of Si |
| No. | film | time | Type | (nm) | properties | diffusion |
| 11 | SiO₂ | 10 min | TiSi | 3 | ◯ | presence |
| 12 | | 20 min | | 8 | ◯ | presence |
| 13 | | 30 min | | 19 | ◯ | presence |
| 14 | | 1 hr | | 42 | ◯ | presence |
| 15 | | 2 hr | | 78 | ◯ | presence |
| 16 | SiCO-1 | 5 min | TiC | 0 | X | absence |
| 17 | | 10 min | | 2 | X | absence |
| 18 | | 20 min | | 4 | ◯ | absence |
| 19 | | 30 min | | 7 | ◯ | absence |
| 20 | | 1 hr | | 13 | ◯ | absence |
| 21 | | 2 hr | | 28 | ◯ | absence |
| 22 | SiCN | 5 min | | 0 | X | absence |
| 23 | | 10 min | | 0 | X | absence |
| 24 | | 20 min | | 0 | X | absence |
| 25 | | 30 min | | 2 | X | absence |
| 26 | | 1 hr | | 6 | ◯ | absence |
| 27 | | 2 hr | | 12 | ◯ | absence |

### Experimental Example 3

This experiment was performed under the same conditions as in Experimental Example 1, except for using a Cu alloy containing 1 atomic percent of Ti as a Cu alloy thin film formed on a surface of the insulating film, and for performing a heat treatment in the horizontal tubular furnace by heating at 400° C. in a vacuum atmosphere [133×10⁻¹⁰ Pa or less (1×10⁻¹⁰ Torr or less)] for 1 to 24 hours. Table 4 shows the type of the insulating film, the heat treatment time, the type and thickness of a barrier film formed between the insulating film and the Cu alloy thin film, the presence or absence of diffusion of Cu into the insulating film (Cu-barrier properties), and the presence or absence of diffusion of Si into the Cu alloy thin film.

Table 4 demonstrates that a compound between a component constituting the insulating film and Ti contained in the Cu alloy was formed between the insulating film and the Cu alloy thin film, under any heat treatment conditions.

Samples Nos. 31 to 35 are samples using SiO₂ to constitute the insulating film and were found to include a TiSi layer as a barrier film formed between the insulating film and the Cu alloy thin film. However, these samples showed diffusion of Si into the Cu alloy thin film and had a higher electrical resistivity of the Cu alloy thin film, because Si acted as a resistance.

In contrast, Samples Nos. 36 to 45 are samples using SiCO-1 or SiCN to constitute the insulating film and were found to include a TiC layer formed between the insulating film and the Cu alloy thin film. Samples Nos. 36 to 45 showed no diffusion of Si into the Cu alloy thin film. However, Samples No. 36 and No. 37 showed diffusion of Cu into the insulating film, because the TiC layer in these samples had a thickness of less than 3 nm and failed to serve as a barrier layer.

TABLE 4

| | | | | | | Presence |
|---|---|---|---|---|---|---|
| | | Heat | Barrier layer | | | or absence |
| | Insulating | treatment | | Thickness | Cu-barrier | of Si |
| No. | film | time | Type | (nm) | properties | diffusion |
| 31 | SiO₂ | 1 hr | TiSi | 0 | X | presence |
| 32 | | 3 hr | | 2.9 | X | presence |
| 33 | | 6 hr | | 6.4 | ◯ | presence |
| 34 | | 12 hr | | 10.9 | ◯ | presence |
| 35 | | 24 hr | | 18.7 | ◯ | presence |
| 36 | SiCO-1 | 1 hr | TiC | 0 | X | absence |
| 37 | | 3 hr | | 2.2 | X | absence |
| 38 | | 6 hr | | 4.6 | ◯ | absence |
| 39 | | 12 hr | | 7.8 | ◯ | absence |
| 40 | | 24 hr | | 10.5 | ◯ | absence |
| 41 | SiCN | 1 hr | | 5.8 | ◯ | absence |
| 42 | | 3 hr | | 9.7 | ◯ | absence |
| 43 | | 6 hr | | 22.1 | ◯ | absence |
| 44 | | 12 hr | | 30.6 | ◯ | absence |
| 45 | | 24 hr | | 41.1 | ◯ | absence |

### Experimental Example 4

In this experiment, how the electrical resistivity of the Cu alloy thin film varies depending on the heat treatment time was investigated.

This experiment was performed under the same conditions as in Experimental Example 3, except for performing the heat treatment in the horizontal tubular furnace for durations of 2 hours, 24 hours, and 72 hours, or performing no heat treatment. The electrical resistivity (pΩcm) of the Cu alloy thin film was determined by measuring the surface resistivity of the Cu alloy thin film of each sample after the heat treatment according to a four-pin probes sensing method; and multiplying the surface resistivity by the film thickness. How the electrical resistivity varies depending on the heat treatment time is shown in FIG. 2. In FIG. 2, the symbol “∘” indicates data obtained by using a SiO₂ film; the symbol “” indicates data obtained by using an SiCO-1 film; and the symbol “Δ” indicates data obtained by using an SiCN film, respectively as the insulating film.

FIG. 2 demonstrates that the electrical resistivity of the Cu alloy thin film decreases with an increasing heat treatment time. This is probably because, while Ti contained in the Cu alloy thin film diffuses to the interface with the insulating film to form a barrier layer, Ti also diffuses to the other side opposite to the insulating film and is exposed to be in contact with outside atmosphere to form an oxide film such as TiO₂ film, thus Ti in the Cu alloy thin film is consumed.

FIG. 2 also demonstrates that, when SiO₂ is used as the insulating film, a heat treatment for 70 hours or longer is required to allow the Cu alloy thin film to have a low electrical resistivity of 5 pΩcm or less; but that, when SiCO-1 or SiCN film is used as the insulating film, a heat treatment for about 20 hours is enough to allow the Cu alloy thin film to have a low electrical resistivity of 5 pΩcm or less.

These results demonstrate that the use of SiCO-1 or SiCN film as the insulating film allows the Cu alloy thin film to have a lower electrical resistivity merely through a heat treatment for a short time and thereby allows the semiconductor interconnection to show higher productivity.

While the present invention has been illustrated in detail with reference to certain embodiments, those skilled in the art will recognize that various modifications and changes are possible without departing from the spirit and scope of the present invention. This application is based on a Japanese patent application filed on Jul. 14, 2008 (Japanese Patent Application No. 2008-183014), entire contents of which are incorporated herein by reference.

### REFERENCE SIGNS LIST

1 semiconductor substrate
2 insulating film
3 trench
4 Cu interconnection
5 TiC layer

1. A semiconductor interconnection comprising:
a semiconductor substrate;
an insulating film arranged on or above the semiconductor substrate; and
a copper (Cu) interconnection containing titanium (Ti); and,
a trench provided in the insulating film,
wherein the copper (Cu) interconnection is embedded in the trench, and
the semiconductor interconnection further comprises a titanium carbide (TiC) layer present between the insulating film and the copper (Cu) interconnection.

2. The semiconductor interconnection according to claim 1, wherein the insulating film comprises SiCO or SiCN.

3. The semiconductor interconnection according to claim 1, wherein the titanium carbide (TiC) layer has a thickness of 3 to 30 nm.
